(19) United States
(12) Patent Application Publication
(10) Pub. No.: US 2012/0149209 A1
(43) Pub. Date: Jun. 14, 2012

(54) PROCESS SEQUENCING FOR HPC ALD SYSTEM

(76) Inventors: Ed Haywood, San Jose, CA (US); Pragati Kumar, Santa Clara, CA (US)

(21) Appl. No.: 12/967,278

(22) Filed: Dec. 14, 2010

(51) Int. Cl. H01L 21/02

(52) U.S. Cl. 438/758; 257/E21.002

(57) ABSTRACT

A combinatorial processing method is provided. The combinatorial processing method includes providing a flow of fluid over segregated sectors of a substrate to process the segregated sectors of the substrate in parallel without significantly exposing any section to a reagent without first applying a film and without subjecting any section to the same process step at the same time. Differently processed, segregated sectors may be generated in parallel.

### TECHNICAL FIELD

This disclosure relates to semiconductor processing. More particularly, this disclosure relates to a processing system and a method of site-isolated vapor based processing to facilitate combinatorial film deposition and integration on a substrate.

### BACKGROUND

Chemical Vapor Deposition (CVD) is a vapor based deposition process commonly used in semiconductor manufacturing including but not limited to the formation of dielectric layers, conductive layers, semiconducting layers, liners, barrier layers, adhesion layers, seed layers, stress layers, and fill layers. CVD is typically a thermally driven process whereby the precursor flux(es) are pre-mixed and coincident to the substrate surface to be deposited upon. CVD requires control of the substrate temperature and the incoming precursor flux(es) to achieve desired film material properties and thickness uniformity. Derivatives of CVD based processes include but are not limited to Plasma Enhanced CVD (PECVD), High-Density Plasma CVD (HDP-CVD), Sub-Atmospheric CVD (SACVD), Laser Assisted/Induced CVD, and Ion Assisted/Induced CVD.

As device geometries shrink and associated film thicknesses decrease, there is an increasing need for improved control of the deposited layers. A variant of CVD that enables superior step coverage, materials property, and film thickness control is a sequential deposition technique known as Atomic Layer Deposition (ALD). ALD is a multi-step, self-limiting process that includes the use of at least two precursors or reagents. Generally, a first precursor (or reagent) is introduced into a processing chamber containing a substrate and adsorbs on the surface of the substrate. Excess first precursor is purged and/or pumped away. A second precursor (or reagent) is then introduced into the chamber and reacts with the initially adsorbed layer to form a deposited layer via a deposition reaction. The deposition reaction is self-limiting in that the reaction terminates once the initially adsorbed layer is consumed by the second precursor. Excess second precursor is purged and/or pumped away. The aforementioned steps constitute one deposition or ALD “cycle.” The process is repeated to form the next layer, with the number of cycles determining the total deposited film thickness. Different sets of precursors can also be chosen to form nano-composites comprised of differing material compositions. Derivatives of ALD include but are not limited to Plasma Enhanced ALD (PEALD), Radical Assisted/Enhanced ALD, Laser Assisted/Induced ALD, and Ion Assisted/Induced ALD.

Conventional vapor-based processes such as CVD and ALD are designed to process uniformly across a full wafer. In addition, these CVD and ALD processes need to be integrated into process/device flows. When used experimentally to accumulate data pertaining to the properties of a particular film, uniform processing results in fewer data per substrate, longer times to accumulate a wide variety of data and higher costs associated with obtaining such data.

### BRIEF DESCRIPTION OF THE DRAWINGS

Various embodiments of the invention are disclosed in the following detailed description and the accompanying drawings:

FIG. 1 is a flowchart depicting a method for combinatorially processing a substrate in accordance with an embodiment of the present disclosure;

FIG. 2 is a flowchart depicting a method for combinatorially processing a substrate in accordance with an alternative embodiment of the present disclosure;

FIG. 3 is a flowchart depicting a method for combinatorially processing a substrate in accordance with an additional embodiment of the present disclosure;

FIG. 4 is a chart showing combinatorial film deposition methodology for producing a multi-segmented substrate with four sectors;

FIG. 5 is a chart showing process steps in accordance with one embodiment of the present disclosure;

FIG. 6 is a detailed cross-sectional view of a system for performing the methods disclosed herein;

FIG. 7 is a bottom-up exploded perspective view of a showerhead assembly employed in a substrate processing system;

FIG. 8 is a top-down exploded perspective view of the showerhead shown in FIG. 7;

FIG. 9 is a top-down view of a manifold body of the showerhead shown in FIGS. 7 and 8;

FIG. 10 is a simplified diagram illustrating the flow vectors for the axi-symmetric segmented flow enabling species isolation to define segregated sectors of the wafer surface;

FIG. 11 is a plan view of a fluid supply apparatus;

FIG. 12 is a graphical representation of the operation of a fluid supply apparatus in FIG. 11 processing a substrate in parallel; and

FIG. 13 is a top-down view of a substrate having material formed thereon in accordance with an embodiment of the present disclosure.

### DETAILED DESCRIPTION

The present disclosure is directed to a method and system for combinatorially processing a substrate. The method and system for combinatorially processing a substrate may process segregated sectors or quadrants of a wafer separately. Advantageously, the substrate processing method of the present disclosure may result in more data per substrate, and shorter data accumulation time with fewer machines and less manpower.

The disclosed method for processing a substrate provides testing of i) more than one material, ii) more than one processing condition, iii) more than one sequence of processing conditions, and iv) more than one process sequence integration flow on a single monolithic substrate, processed in parallel. This can greatly improve the speed and reduce the costs associated with the implementation, optimization, and qualification of new CVD and ALD based material(s), process(es), and process integration sequence(s) required for manufacturing. The disclosure provides methods for processing substrates in a combinatorial manner by offsetting the process cycle for each sector of the substrate.

The embodiments described herein provide a method for evaluating materials, unit processes, and process integration sequences to improve semiconductor manufacturing operations. The present method may be practiced without some or all of these specific details. In other instances, well known process operations have not been described in detail in order not to unnecessarily obscure the present method.

Substrate processing method may allow all sectors of a substrate to be processed simultaneously, without ever requiring adjustments to a rate of carrier or reagent gas flow, and without significantly exposing sectors of the substrate to a reagent before they have been deposited with a film.

In ALD processing, a carrier gas distributes a precursor over the surface of the substrate. For ALD processing to function properly, precursors are applied at a consistent partial pressure relative to the pressure of the carrier gas. Any deviation from that partial pressure can alter the overall precursor deposition which could affect the thickness and material properties of that layer and thereby taint any data derived from the substrate.

Maintaining consistent precursor partial pressure during each deposition cycle allows consistent data from the substrate being processed. In combinatorial film deposition, as some sectors complete processing before others, and the number of sectors being processed is reduced, a substrate processing system can maintain consistent partial pressure by varying the carrier gas flow rate. Substrate processing method of the present disclosure deposits precursors at a consistent partial pressure without varying the carrier gas flow rate, even as the number of sectors being deposited with a precursor is reduced.

Another advantage of the present method over existing technology is that a substrate processing system implementing the present method can process individual sectors of a substrate differently, without significantly exposing adjacent sectors of the substrate to a reagent before applying a film. Exposing a substrate to a reagent without a film can damage the substrate. Ordinary serial processing of a substrate divided into sectors carries a danger of significantly exposing a sector of the substrate to a reagent fluid before depositing a film.

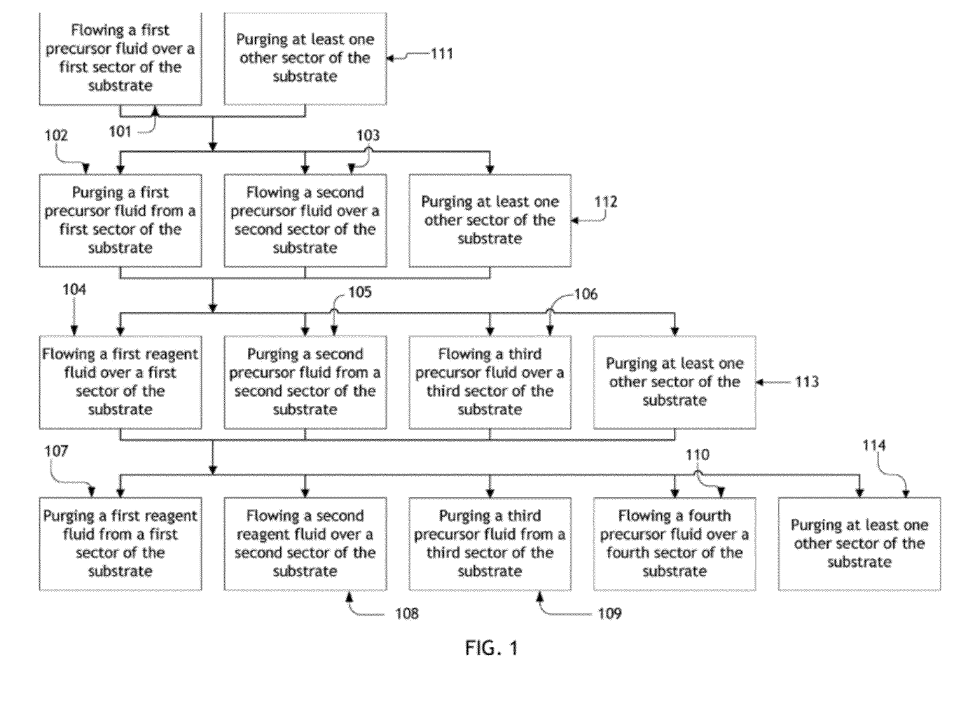

Referring to FIG. 1, a substrate processing method in accordance with an embodiment of the disclosure is shown. Substrate processing method may include purging a first precursor fluid from a first sector of the substrate 102 while at the same time flowing a second precursor fluid over a second sector of the substrate 103; then flowing a first reagent fluid over the first sector of the substrate 104 while at the same time purging the second precursor fluid from the second sector of the substrate 105; and then purging the first reagent fluid from the first sector of the substrate 107 while at the same time flowing a second reagent fluid over the second sector of the substrate 108. A substrate processing system may perform additional steps in the ALD or CVD cycles either prior to the steps listed or after the steps listed. By this methodology, a substrate processing system may process two sectors of a substrate in parallel. Parallel processing of two sectors of a substrate is useful when processing a substrate divided into two sectors, and also during processing of a substrate divided into more than two sectors. As one or more sectors of the substrate have completed processing, other sectors may continue processing. A substrate processing system processing a substrate divided into more than two sectors may further purge at least one additional sector of the substrate, such as third and fourth sectors.

The substrate processing method described above may further comprise the steps of, while flowing a first reagent fluid over the first sector of the substrate 104 and purging the second precursor fluid from the second sector of the substrate 105, flowing a third precursor fluid over a third sector of the substrate 106; and, while purging the first reagent fluid from the first sector of the substrate 107 and flowing a second reagent fluid over the second sector of the substrate 108, purging the third precursor fluid from the third sector of the substrate 109.

A substrate processing system may perform additional steps in the ALD or CVD cycles either prior to the steps listed or after the steps listed. By this methodology, a substrate processing system may process three sectors of a substrate in parallel. The steps listed are indicative of one embodiment of the initial steps of substrate processing for a substrate divided into three or more sectors. A substrate processing system processing a substrate divided into more than three sectors may further purge at least one additional sector, such as a fourth sector of the substrate.

The method described in the preceding paragraph may further include while purging the first reagent fluid from the first sector of the substrate 107, flowing a second reagent fluid over the second sector of the substrate 108 and purging the third precursor fluid from the third sector of the substrate 109, flowing a fourth precursor fluid over a fourth sector of the substrate 110. A substrate processing system may perform additional steps in the ALD or CVD cycles either prior to the steps listed or after the steps listed. By this methodology, a substrate processing system may process four sectors of a substrate in parallel. The steps listed are indicative of one embodiment of the initial steps of substrate processing for a substrate divided into four or more sectors. A substrate processing system processing a substrate divided into more than four sectors may further purge at least one additional sector of the substrate, such as a fifth sector of the substrate.

In this embodiment, processing commences when a first sector of the substrate is exposed to a first precursor fluid while all other sectors of the substrate are purged; then a second sector of the substrate is exposed to a second precursor fluid while all other sectors of the substrate are purged; then the first sector of the substrate is exposed to a first reagent fluid, a third sector of the substrate is exposed to a third precursor fluid and all other sectors of the substrate are purged; then the second sector of the substrate is exposed to a second reagent fluid while a fourth sector of the substrate is exposed to a fourth precursor fluid and all other sectors of the substrate are purged. A substrate processing system may then continue processing the substrate according to the usual processing sequence for each sector. By this method, a substrate processing system may commence processing four sectors of a substrate in parallel, while never exposing two sectors of the substrate to a precursor fluid or a reagent fluid.

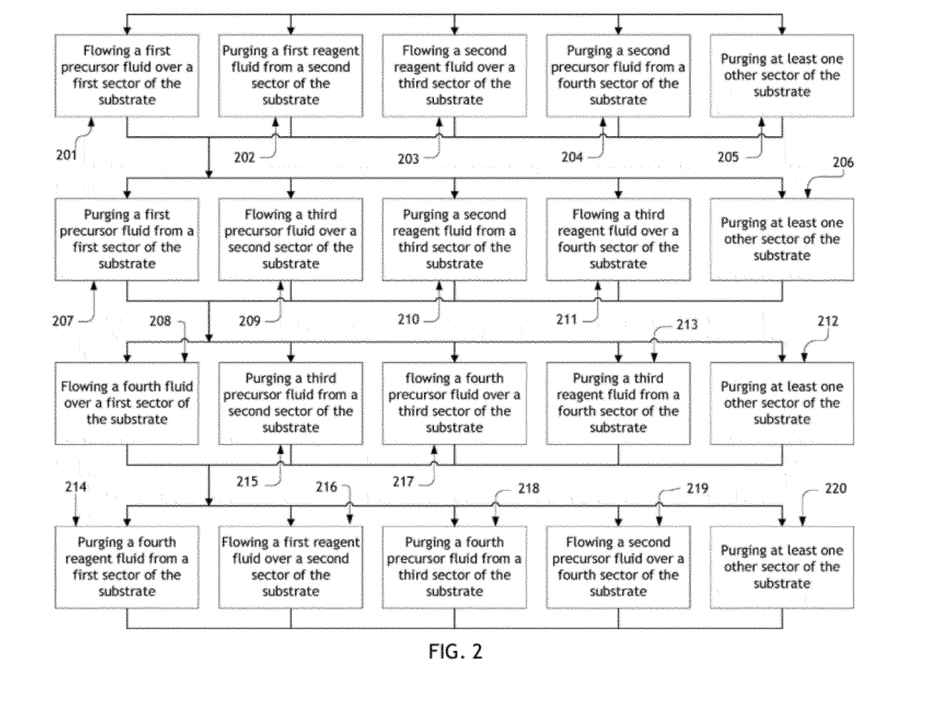

Referring to FIG. 2, a substrate processing method includes flowing a first precursor fluid over a first sector of the substrate 201 while purging a first reagent fluid from a second sector of the substrate 202, flowing a second reagent fluid over a third sector of the substrate 203 and purging a second precursor fluid from a fourth sector of the substrate 204. By this method, a substrate processing system may continue processing four sectors of a substrate in parallel, while never exposing two sectors to a precursor fluid or a reagent fluid during any individual process step. This method is not limited to substrates divided into four sectors; a substrate processing system implementing this method may process substrates divided into more than four sectors by incorporating purging at least one additional sector of the substrate, such as a fifth sector of the substrate 205.

The method described in the preceding paragraph may further include purging the first precursor fluid from the first sector of the substrate 207 while flowing a third precursor fluid over the second sector of the substrate 209, purging the second reagent fluid from the third sector of the substrate 210 and flowing a third reagent fluid over the fourth sector of the substrate 211. This method may further comprise then flowing a fourth reagent fluid over the first sector of the substrate 208 while purging the third precursor fluid from the second sector of the substrate 215, flowing a fourth precursor fluid over the third sector of the substrate 217 and purging the third reagent fluid from the fourth sector of the substrate 213. This method may further comprise then purging the fourth reagent fluid from the first sector of the substrate 214 while flowing the first reagent fluid over the second sector of the substrate 216, purging the fourth precursor fluid from the third sector of the substrate 218 and flowing the second precursor fluid over the fourth sector of the substrate 219. The steps of this method, performed repeatedly and cyclically until processing of each sector of the substrate is complete, constitute one embodiment for processing a substrate divided into four sectors, in parallel.

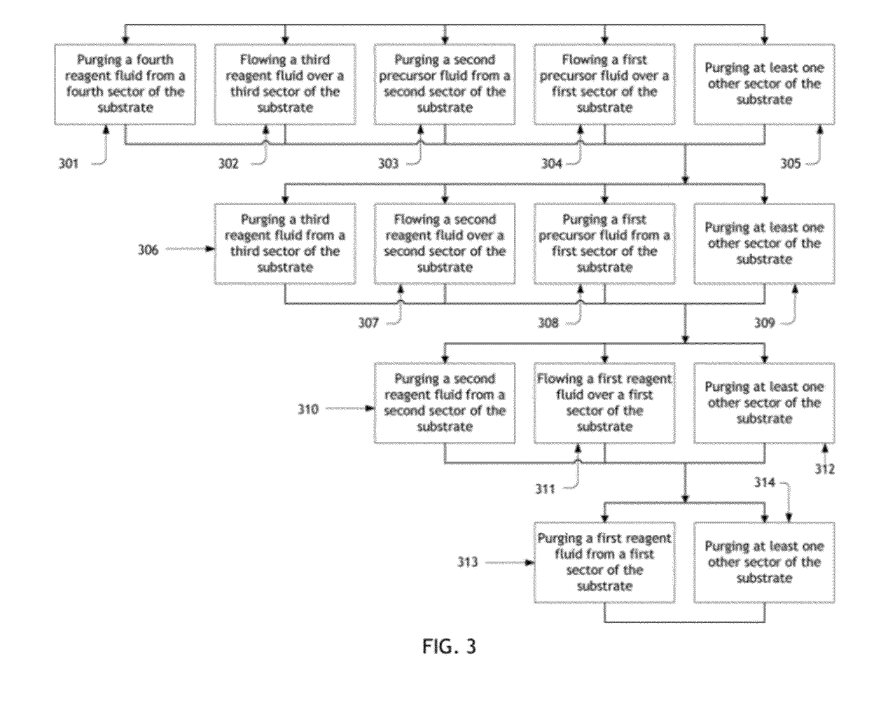

Referring to FIG. 3, a substrate processing method includes flowing a first reagent fluid over a first sector of the substrate 311 while purging a second reagent fluid from a second sector of the substrate 310; then purging the first reagent fluid from the first sector of the substrate 313. This method may further include purging at least one sector of the substrate that is not one of the first sector and the second sector 312 and 314. A substrate processing system may perform additional steps in the ALD or CVD cycles either prior to the steps listed or after the steps listed. By this method, a substrate processing system may conclude processing one sector of a substrate while continuing to process one or more additional sectors of a substrate without altering carrier gas flow rates.

The method of the preceding paragraph may further include the preceding steps of purging a first precursor fluid from the first sector of the substrate 308 while flowing the second reagent fluid over the second sector of the substrate 307 and purging a third reagent fluid from a third sector of the substrate 306. This method may further include purging at least one additional sector of the substrate, such as a sector that is not one of the first sector, the second sector and the third sector 309, 312 and 314. A substrate processing system may perform additional steps in the ALD or CVD cycles either prior to the steps listed or after the steps listed. A substrate processing system may also perform additional steps in the ALD or CVD cycles after purging the third reagent fluid from the third sector of the substrate 306, but before purging the second reagent fluid from the second sector of the substrate 310. By this method, a substrate processing system may conclude processing one sector of a substrate while continuing to process two or more additional sectors of a substrate without altering carrier gas flow rates.

The method of the preceding paragraph may further include the preceding steps of flowing the first precursor fluid over the first sector of a substrate 304 while purging a second precursor fluid from the second sector of the substrate 303, flowing the third reagent fluid over the third sector of the substrate 302 and purging a fourth reagent fluid from a fourth sector of the substrate 301. This method may further include purging at least one sector of the substrate, such as a fifth sector of the substrate, that is not one of the first sector, the second sector, the third sector and the fourth sector 305, 309, 312 and 314. A substrate processing system may perform additional steps in the ALD or CVD cycles either prior to the steps listed or after the steps listed. A substrate processing system may also perform additional steps in the ALD or CVD cycles after purging the fourth reagent fluid from the fourth sector of the substrate 301, but before purging the third reagent fluid from the third sector of the substrate 306. By this method, a substrate processing system may conclude processing one sector of a substrate while continuing to process three or more additional sectors of a substrate without altering carrier gas flow rate.

In the above embodiments, the first precursor fluid may be chemically identical to at least one of the second precursor fluid, the third precursor fluid and the fourth precursor fluid. Likewise, the first reagent fluid may be chemically identical to at least one of the second reagent fluid, the third reagent fluid and the fourth reagent fluid. In an alternative embodiment, the first precursor fluid may be different from at least one of the second precursor fluid, the third precursor fluid and the fourth precursor fluid. Likewise, the first reagent fluid may be different from at least one of the second reagent fluid, the third reagent fluid and the fourth reagent fluid. In such a fashion, combinatorial processing of sectors of the substrate may be developed and tested.

It is further contemplated that substrate processing method of FIG. 3 illustrates an embodiment wherein one sector of a substrate concludes processing on each successive process step. While such an embodiment is disclosed, in actual application, a substrate processing system would likely perform a plurality of ALD or CVD cycles on the remaining sector or sectors of the substrate at the conclusion of processing for each sector of the substrate.

Referring to FIG. 4, a chart showing combinatorial film deposition methodology for producing a multi-segmented substrate with four sectors is shown. Sector 1 of a substrate undergoing serial processing will complete multiple ALD or CVD cycles before any other sector of the substrate undergoes even a single cycle. A substrate processing system implementing existing processes could expose sectors adjacent to Sector 1 to the reagent fluid. Implementations of combinatorial film deposition may attempt to limit exposure to adjacent sectors through a fluid separation mechanism, but such mechanisms may not be able to completely prevent significant, incidental exposure of adjacent sectors to a reagent fluid. By implementing embodiments of the present method, every sector of a substrate is deposited with a film before any sector is significantly exposed to a reagent fluid.

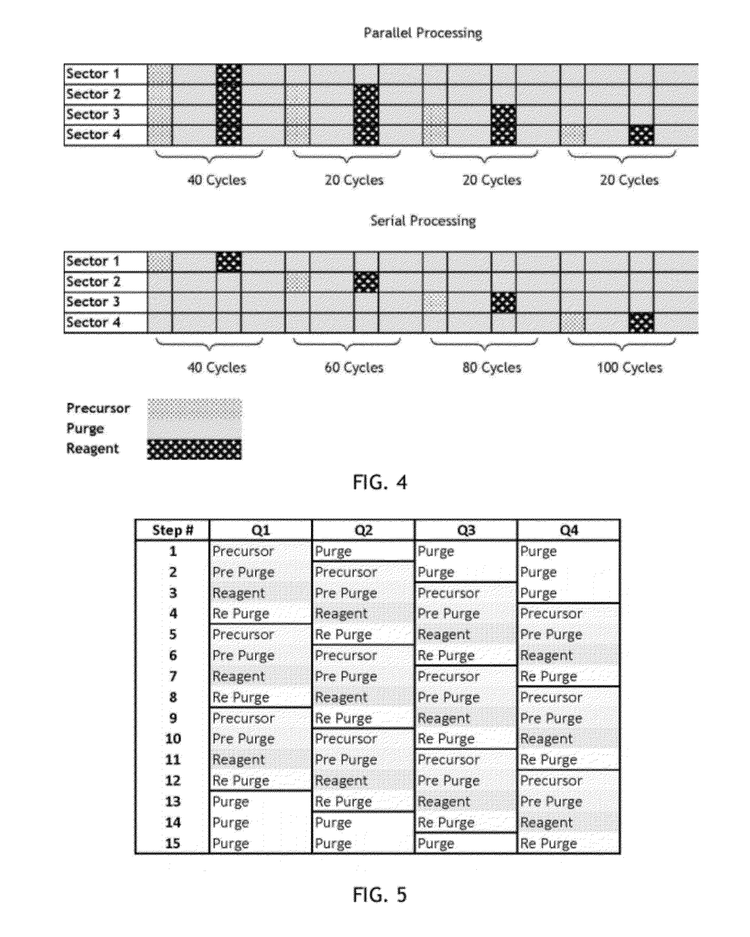

FIG. 5 is a chart showing process steps of a substrate processing method in accordance with one embodiment of the present disclosure. Substrate processing method may be exemplary of a four quadrant substrate processing method whereby every sector of a substrate is deposited with a film before any sector is significantly exposed to a reagent fluid without modification of carrier gas flow rates.

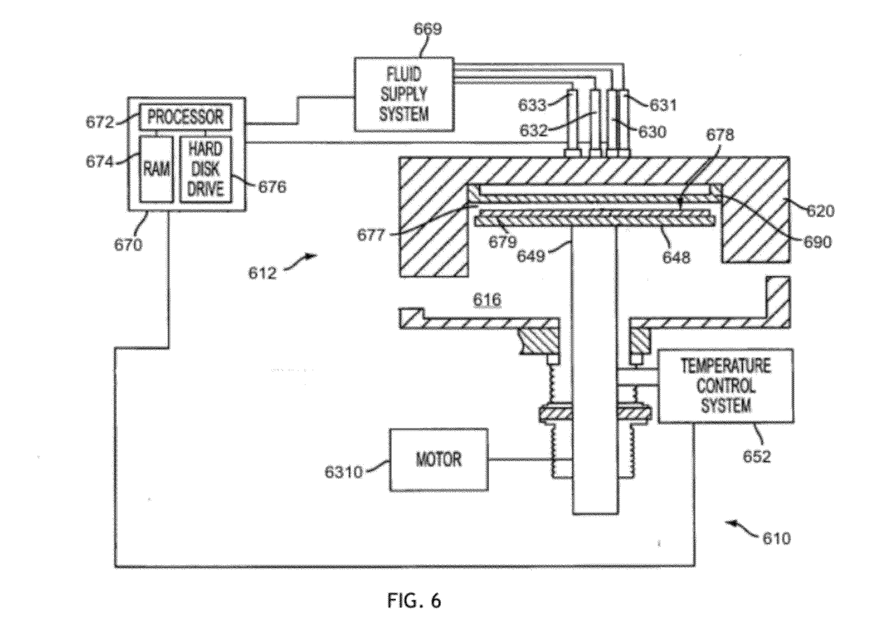

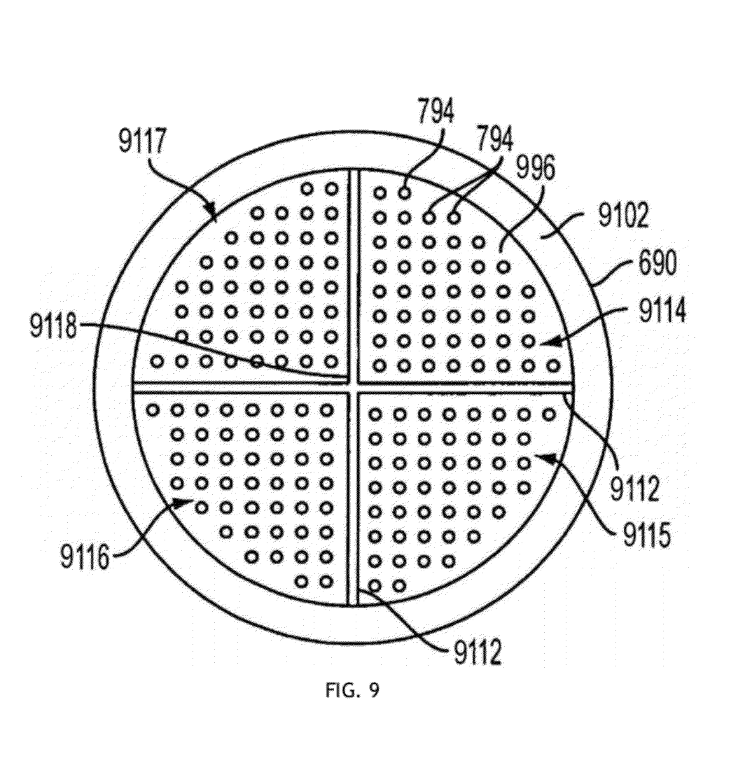

Referring generally to FIGS. 6-13, a combinatorial film deposition apparatus is shown. Combinatorial film deposition apparatus may include a fluid supply apparatus and a fluid application control apparatus operably connected to the fluid supply apparatus. The fluid application control apparatus may include a processor and a memory connected to the processor. The combinatorial film deposition apparatus may further include a plurality of injection ports functionally connected to the fluid supply apparatus and a fluid distribution apparatus connected to each of the plurality of injection ports. The fluid supply apparatus is configured to deliver a separate fluid to each injection port independently and is configured to deliver fluid from each of the injection ports to a separate sector of a substrate. The fluid application control apparatus is configured to direct the fluid supply apparatus to flow a first precursor fluid over a first sector of a substrate, purge a second precursor fluid from a second sector of the substrate, flow a first reagent fluid over a third sector of the substrate and purge a second reagent fluid from a fourth sector of the substrate, simultaneously.

Referring to FIG. 6, a substrate processing system 610 operable to execute substrate processing methods as described in FIGS. 1-5 is shown. Substrate processing system 610 may include an enclosure assembly 612 formed from a process-compatible material, such as aluminum or anodized aluminum. The enclosure assembly 612 includes a housing defining a processing chamber 616 and a vacuum lid assembly 620 covering an opening to processing chamber 616. Mounted to vacuum lid assembly 620 is a process fluid injection assembly that delivers reactive and carrier fluids into processing chamber 616. To that end, the fluid injection assembly includes a plurality of passageways 630, 631, 632 and 633 and a showerhead 690. The chamber 616, vacuum lid assembly 620, and showerhead 690 may be maintained within desired temperature ranges in a conventional manner. It should be appreciated that the figures provided herein are illustrative and not necessarily drawn to scale.

Fluid supply system 669 may be in fluid communication with passageways 630, 631, 632 and 633 through a sequence of conduits. A controller 670 regulates operations of the various components of system 610. Controller 670 includes a processor 672 in data communication with memory, such as random access memory 674 and a hard disk drive 676 and is in signal communication with temperature control system 652, fluid supply system 669 and various other aspects of the system as required.

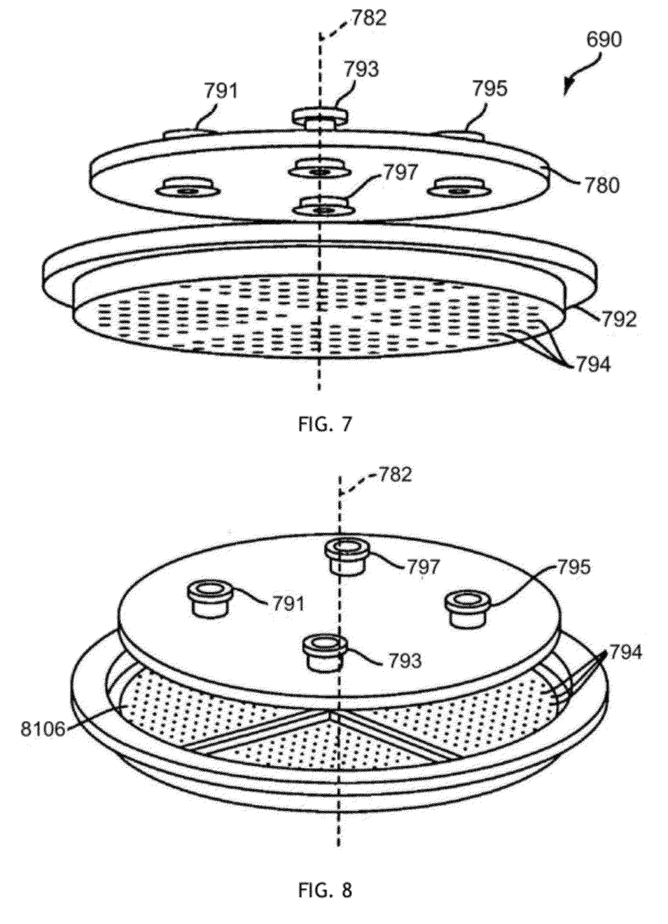

Referring to FIGS. 7, 8 and 9, showerhead 690 may include a baffle plate 780 that is formed to be radially symmetric about a central axis 782, but need not be. Baffle plate 780 has a plurality of through ports 791, 793, 795 and 797 extending therethrough. Coupled to baffle plate 780 is a manifold portion 792 having a plurality of injection ports 794 extending through manifold portion 792. Manifold portion 792 is typically disposed to be radially symmetric about axis 782. Manifold portion 792 is spaced-apart from a surface to define a plenum chamber 8106 therebetween. Manifold portion 792 may be coupled to baffle plate 780 using any means known in the semiconductor processing art, including fasteners, welding and the like. Baffle plate 780 and shower head 690 may be formed from any known material suitable for the application, including stainless steel, aluminum, anodized aluminum, nickel, ceramics and the like.

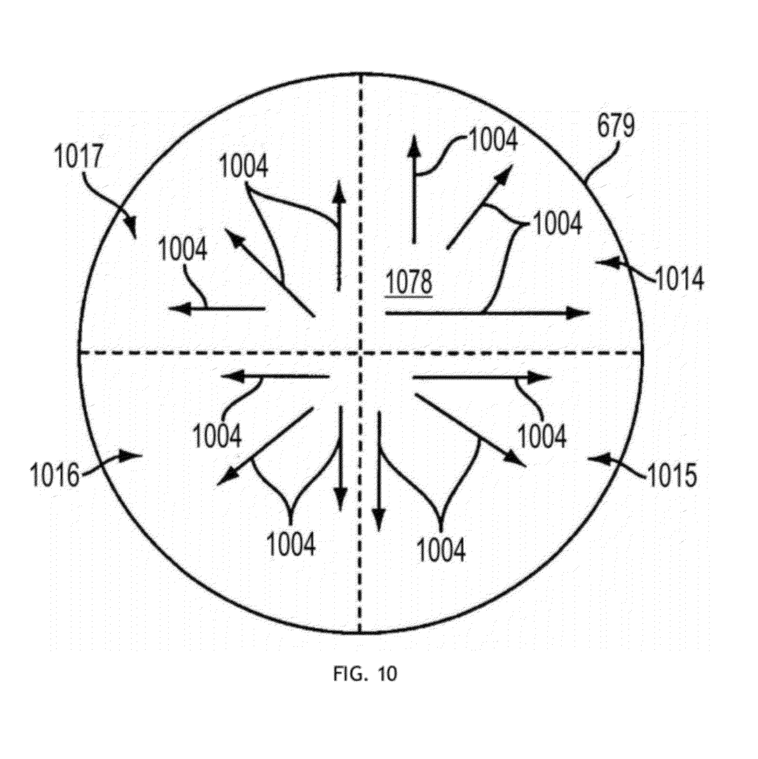

Referring to FIGS. 6 and 10, fluid supply system 669 allows a carrier, precursor fluid and reagent fluid into processing chamber 616 to provide, from the selected fluids, a volume of fluid passing over surface 678 of substrate 679. Portions of the fluid volume have different constituent components so that differing regions of surface 678 of substrate 679 may be exposed to those different constituent components at the same time. The volume of fluid passing over surface 678 is generated by processing fluids propagating via injection ports 794 into processing chamber 616. The fluid distribution system enables exposing each of sectors 1014-1017 of substrate 679 to the constituent components of the portion of the volume of fluid propagating through injection ports 794 associated with one of showerhead sectors 9114-9117 corresponding therewith (i.e., directly above or in superimposition with). Each substrate sector 1014-1017 of substrate 679 is exposed to the fluid volume from the showerhead sectors 9114-9117 that is corresponding therewith out being exposed to constituent components of the portion of the volume of fluid propagating through the other showerhead sectors 9114-9117. In the present example, showerhead sector 9114 corresponds with substrate sector 1014, showerhead sector 9115 corresponds with substrate sector 1015, showerhead sector 9116 corresponds with substrate sector 1016 and showerhead sector 9117 corresponds with substrate sector 1017. The showerhead sectors can correspond with other sectors of the substrate, or the corresponding showerhead sector and substrate sector can be changed during in between processing by rotating the substrate relative to the showerhead (e.g., by a full or partial region/quadrant).

Fluid supply system 669 controls the distribution of the processing fluids so that the total flow through the showerhead assembly is symmetric through the showerhead sectors although the constituent processing fluids per sector are altered as a function of time. This serves to facilitate axi-symmetric flow. Moreover, the chamber pressure can be controlled to a fixed pressure (e.g., 1 mTorr to 610 Torr) during such operations. In addition, other chamber wide parameters can be controlled by known techniques.

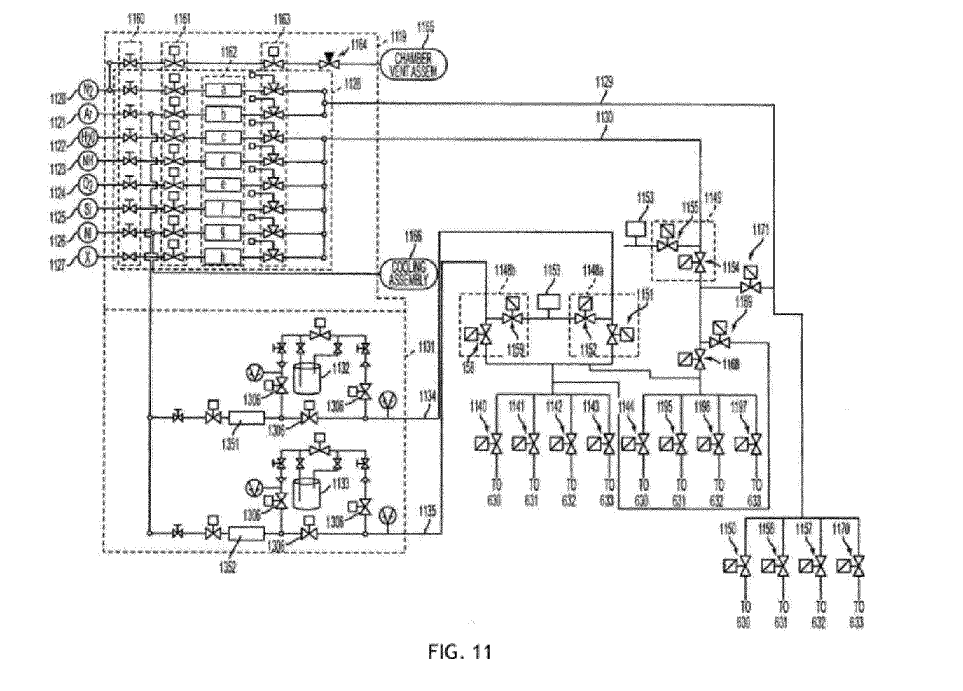

Referring to FIGS. 6 and 11, another embodiment of fluid supply system 669 includes precursor/reagent fluid subsystems 1119 and 1131, valve blocks 1148a, 1148b and 1149. An additional set of valves 1150, 1156, 1157 and 1170 are in fluid communication with passageways 630-633, configured to facilitate delivering processing gases to more than one of quadrants 1114-1117 concurrently. To that end, valve 1151 of valve block 1148a functions to selectively place fluid line 1134 in fluid communication with valves 1144, 1195, 1196 and 1197, thereby facilitating concurrent introduction of processing fluids into processing chamber 616 from fluid lines 1134 and 1135; however, it will be appreciated that the fluid supply system will supply no more than one of quadrants 9114-9117 with a precursor fluid at any one time, and no more than one of quadrants 9114-9117 with a reagent fluid at any one time. Valve 1168 facilitates selectively placing processing fluids in fluid line 1130 in fluid communication with valves 1144, 1195, 1196 and 1197, and valve 1169 facilitates selectively placing processing fluids in fluid line 1130 in fluid communication with valves 1140-1143. Valve 1171 facilitates selectively placing processing fluids in fluid line 1130 in fluid communication with valves 1150, 1156, 1157 and 1170. Greater flexibility in the constituent components in the processing volume proximate to surface 678 is afforded with this valve configuration.

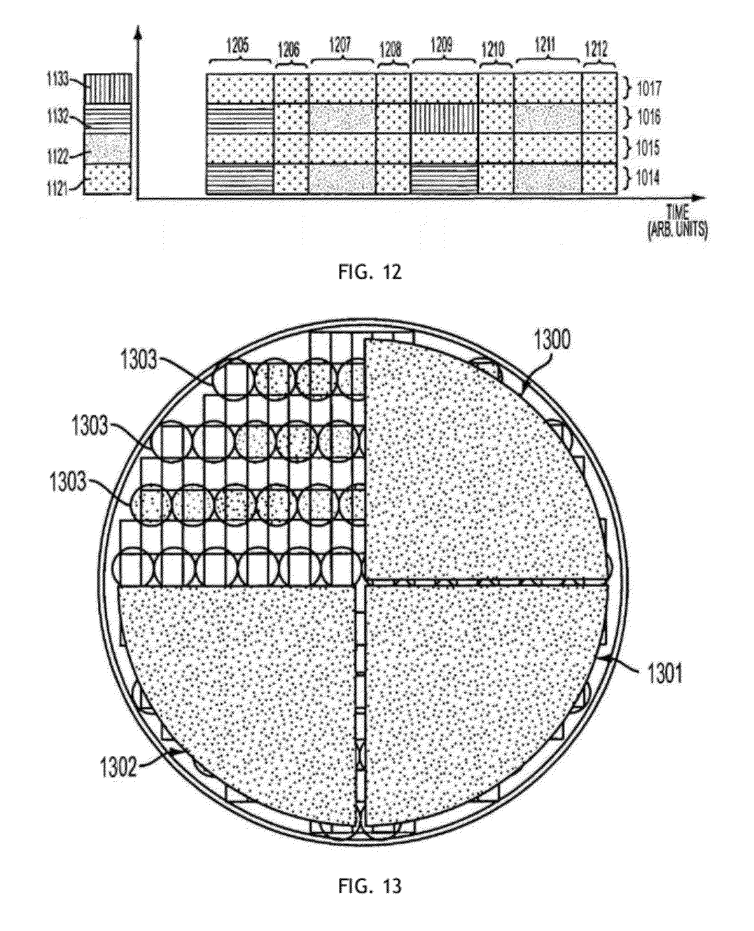

FIG. 12 illustrates one type of parallel processing. Using the fluid supply system of FIG. 11 a substrate processing system exposes two sectors of substrate 679, shown in FIG. 10, to precursor fluids (same or different by region) at the same time (i.e., in parallel), In FIG. 12, a substrate processing system processes regions 1014 and 1016 in parallel in a similar fashion for the first ALD cycle (i.e., steps 1205, 1206, 1207, 1208), whereas the substrate processing system processes regions 1014 and 1016 in parallel in a different fashion (i.e., different reagents in step 1209) in the second ALD cycle (i.e., steps 1209, 1210, 1211, 1212). In FIG. 12, each precursor/reagent step is followed by a chamber purge across all regions, as shown, but need not be. In this implementation, carrier gas flow rate would be initially calculated based on precursor deposition on two sectors at one time. If it were desirable to halt precursor deposition on one sector but continue precursor deposition on the other sector, carrier gas flow rates may have to be recalculated, as well as corresponding reagent flow rates. One advantage of the present method is to obviate the necessity of ever adjusting flow rates during processing of a substrate. By removing the need to adjust flow rates in certain processing methodologies, increased efficiency is achieved, and a potential source of human error is removed.

Referring once again to FIGS. 7-9, an embodiment of a fluid application control apparatus, or showerhead, adapted for combinatorial film deposition of a substrate divided into four sectors is shown. The steps outlined in FIG. 1 are in accordance with an embodiment of the present disclosure to begin combinatorial file deposition of a substrate divided into four sectors 1014, 1015, 1016 and 1017 in FIG. 10. Combinatorial film deposition is commenced by flowing a first precursor fluid over a first sector of the substrate 1014; then purging the first precursor fluid from the first sector of the substrate 1014 while flowing a second precursor fluid over a second sector of the substrate 1015; then flowing a first reagent fluid over the first sector of the substrate 1014 while purging the second precursor fluid from the second sector of the substrate 1015 and flowing a third precursor fluid over a third sector of the substrate 1017; then purging the first reagent fluid from the first sector of the substrate 1014 while flowing a second reagent fluid over the second sector of the substrate 1015, purging the third precursor fluid from the third sector of the substrate 1017 and flowing a fourth precursor over a fourth sector of the substrate 1016. It is apparent that by this embodiment, when any reagent fluid is first flowed over any sector of the substrate 1014, the adjacent sectors of the substrate 1015 and 1017 have been or are contemporaneously flowed with a precursor; and the final sector 1016 to be flowed with a precursor is never adjacent to a sector being flowed with a reagent until it is contemporaneously flowed with a precursor.

A substrate processing system 610 configured to apply a precursor, purge a precursor, apply a reagent, and purge a reagent simultaneously to different sectors of the same substrate is also provided. The substrate processing system comprises a fluid supply system 669, a fluid application control apparatus 670 operably connected to the fluid supply system 669 including a processor 672 and memory 674, 676 connected to the processor 672, a plurality of injection ports 630, 631, 632 and 633 functionally connected to the fluid supply system 669 and a fluid distribution apparatus 690 connected to each of the plurality of injection ports. Fluid supply system 669 is configured to deliver a separate fluid to each injection port independently. Fluid distribution apparatus 690 may be further configured to deliver a fluid from each of the injection ports to a separate sector of a substrate. Fluid application control apparatus 670 is configured to direct the fluid supply system 669 to flow a precursor fluid over a first sector of a substrate, purge a precursor fluid from a second sector of the substrate, flow a reagent fluid over a third sector of the substrate and purge a reagent fluid from a fourth sector of the substrate, simultaneously.

The chamber or system described in FIG. 6, or another chamber constructed according to or to implement the methods described herein may include a motor 6310 coupled to cause support shaft 649 and, therefore, support pedestal 648 to rotate about a central axis. A rotary vacuum seal such as a ferrofluidic seal can be used to maintain vacuum during rotation. It is understood that the showerhead in the chamber could also be rotated to create the same effect described below for the pedestal rotation.

With reference to FIG. 13 it is possible to combine different types of combinatorial processing. These different types may include, for example, site isolated regions processed by a PVD mask based technique and the isolated sector based system described herein. For example, combinatorial regions 1300, 1301, 1302 may be created with the system described herein on a substrate that already contains regions 1303 formed with PVD or other techniques, such as wet processing (including electroless deposition, electrochemical deposition, cleaning, monolayer formation, etc.). By combining these combinatorial techniques additional experiments can be conducted and the number of substrates used can be reduced while the amount of information gathered is increased.

The embodiments described above enable rapid and efficient screening of materials, unit processes, and process sequences for semiconductor manufacturing operations. Various layers may be deposited onto a surface of a substrate combinatorially within the same plane, on top of each other or some combination of the two, through the atomic layer deposition tool described herein. In one embodiment, the combinatorial process sequencing takes a substrate out of the conventional process flow, and introduces variation of structures or devices on a substrate in an unconventional manner, i.e., combinatorially. However, actual structures or devices are formed for analysis. That is, the layer, device element, trench, via, etc., are equivalent to a layer, device element, trench, via, etc., defined through a conventional process. The embodiments described herein can be incorporated with any semiconductor manufacturing operation or other associated technology, such as process operations for flat panel displays, optoelectronics devices, data storage devices, magneto electronic devices, magneto optic devices, packaged devices, and the like. The embodiments described herein enable the application of combinatorial techniques to deposition process sequence integration in order to arrive at a globally optimal sequence of semiconductor manufacturing operations by considering interaction effects between the unit manufacturing operations on multiple regions of a substrate concurrently. Specifically, multiple process conditions may be concurrently employed to effect such unit manufacturing operations, as well as material characteristics of components utilized within the unit manufacturing operations, thereby minimizing the time required to conduct the multiple operations. A global optimum sequence order can also be derived and as part of this technique, the unit processes, unit process parameters and materials used in the unit process operations of the optimum sequence order are also considered.

The embodiments are useful for analyzing a portion or sub-set of the overall deposition process sequence used to manufacture a semiconductor device. The process sequence may be one used in the manufacture of integrated circuits (IC) semiconductor devices, data storage devices, photovoltaic devices, and the like. Once the subset of the process sequence is identified for analysis, combinatorial process sequence integration testing is performed to optimize the materials, unit processes and process sequence for that portion of the overall process identified. During the processing of some embodiments described herein, the deposition may be used to form, modify, or complete structures already formed on the substrate, which structures are equivalent to the structures formed during manufacturing of substrates for production. For example, structures on semiconductor substrates may include, but would not be limited to, trenches, vias, interconnect lines, capping layers, masking layers, diodes, memory elements, gate stacks, transistors, or any other series of layers or unit processes that create a structure found on semiconductor chips. The material, unit process and process sequence variations may also be used to create layers and/or unique material interfaces without creating all or part of an intended structure, which allows more basic research into properties of the resulting materials as opposed to the structures or devices created through the process steps. While the combinatorial processing varies certain materials, unit processes, or process sequences, the composition or thickness of the layers or structures or the action of the unit process is preferably substantially uniform within each region, but can vary from region to region per the combinatorial experimentation.

The result is a series of sectors on the substrate that contain structures or results of unit process sequences that have been uniformly applied within that region and, as applicable, across different regions through the creation of an array of differently processed regions due to the design of experiment. This process uniformity allows comparison of the properties within and across the different regions such that the variations in test results are due to the varied parameter (e.g., materials, unit processes, unit process parameters, or process sequences) and not the lack of process uniformity. However, non-uniform processing of regions can also be used for certain experiments of types of screening. Namely, gradient processing or regional processing having non-uniformity outside of manufacturing specifications may be used in certain situations.

Combinatorial processing is generally most effective when used in a screening protocol that starts with relatively simple screening, sometimes called primary screening, and moves to more complex screening involving structures and/or electrical results, sometimes called secondary screening, and then moves to analysis of the portion of the process sequence in its entirety, sometimes called tertiary screening. The names for the screening levels and the type of processing and analysis are arbitrary and depend more on the specific experimentation being conducted. Thus, the descriptions above are not meant to be limiting in any fashion. As the screening levels progress, materials and process variations are eliminated, and information is fed back to prior stages to further refine the analysis, so that an optimal solution is derived based upon the initial specification and parameters.

In vapor based processing, such as ALD or CVD, examples of conditions that may be varied include the precursors, reagents, carrier gases, order of precursors, concentration of precursors/reagents, duration of precursor/reagent pulses, purge fluid species, purge fluid duration, partial pressures, total pressure, flow rates, growth rate per cycle, incubation period, growth rate as a function of substrate type, film thickness, film composition, nano-laminates (e.g., stacking of different ALD film types), precursor source temperatures, substrate temperatures, temperature for saturate adsorption, temperature window for ALD, temperature for thermal decomposition of the precursor(s), plasma power for plasma/ion/radical based ALD, etc. A primary screen may start with varying the precursor and purge fluid pulse durations and flows at increasing substrate temperatures to determine the ALD process window (a zone characterized by self-limiting deposition with weak temperature dependence) for a given film type. A secondary screen may entail stacking two or more such ALD films to vary the effective dielectric constant of a film stack in, for example, a simple MIM capacitor structure. The output of such a screen may be those candidates which yield the highest effective dielectric constant at the lowest leakage and remain stable through a high temperature (e.g. >500 degrees Celsius) thermal anneal. The system and methods described below are useful to implement combinatorial experimentation as described above, and are particularly useful for vapor based processing such as ALD and CVD processing.

Fluid as used in this application refers to liquids, gases, vapors, i.e., a component that flows, and other types of fluids used in ALD and CVD processes and their variants and these terms are used interchangeably throughout this specification. A constituent component may be a liquid at some point in the system. The fluid may be converted to a gas, vapor or other such fluid before entering the processing chamber and being exposed to the substrate.

Although the disclosure has been described in terms of specific embodiments, one skilled in the art will recognize that various modifications may be made that are within the scope of the present disclosure. For example, although four quadrants are shown, any number of quadrants may be provided, depending upon the number of differing process fluids employed to deposit material. Therefore, the scope of the disclosure should not be limited to the foregoing description. Rather, the scope of the disclosure should be determined based upon the claims recited herein, including the full scope of equivalents thereof.

What is claimed:

1. A method of processing a substrate, comprising:
a) purging a first precursor fluid from a first sector of the substrate;
b) while a), flowing a second precursor fluid over a second sector of the substrate;
c) flowing a first reagent fluid over the first sector of the substrate;
d) while c), purging the second precursor fluid from the second sector of the substrate;
e) purging the first reagent fluid from the first sector of the substrate; and
f) while e), flowing a second reagent fluid over the second sector of the substrate, wherein a), c), and e) are performed sequentially.

2. The method of claim 1 wherein the first precursor fluid is chemically identical to the second precursor fluid.

3. The method of claim 1 wherein the first reagent fluid is chemically identical to the second reagent fluid.

4. The method of claim 1 further comprising purging a third sector of the substrate.

5. The method of claim 1 further comprising:
g) while c) and d), flowing a third precursor fluid over a third sector of the substrate; and
h) while e) and f), purging the third precursor fluid from the third sector of the substrate.

6. The method of claim 5 wherein the third precursor fluid is chemically identical to at least one of the first precursor fluid and the second precursor fluid.

7. The method of claim 5 further comprising purging a fourth sector of the substrate.

8. The method of claim 5 further comprising:
i) while e), f) and h), flowing a fourth precursor fluid over a fourth sector of the substrate.

9. The method of claim 8 wherein the fourth precursor fluid is chemically identical to at least one of the first precursor fluid, the second precursor fluid and the third precursor fluid.

10. A method of processing a substrate, comprising:
a) flowing a first precursor fluid over a first sector of the substrate;
b) while a), purging a first reagent fluid from a second sector of the substrate; and
c) while a) and b), flowing a second reagent fluid over a third sector of the substrate;
d) while a), b) and c), purging a second precursor fluid from a fourth sector of the substrate.

11. The method of claim 10 further comprising:
e) purging the first precursor fluid from the first sector of the substrate;
f) while e), flowing a third precursor fluid over the second sector of the substrate;
g) while e) and f), purging the second reagent fluid from the third sector of the substrate; and
h) while e), f) and g), flowing a third reagent fluid over the fourth sector of the substrate, wherein a) and e) are performed sequentially.

12. The method of claim 11 further comprising:
i) flowing a fourth reagent fluid over the first sector of the substrate;
j) while i), purging the third precursor fluid from the second sector of the substrate;
k) while i) and j), flowing a fourth precursor fluid over the third sector of the substrate; and
l) while i), j) and k), purging the third reagent fluid from the fourth sector of the substrate, wherein a), e) and i) are performed sequentially.

13. The method of claim 12 further comprising:
m) purging the fourth reagent fluid from the first sector of the substrate;
n) while m), flowing the first reagent fluid over the second sector of the substrate;
o) while m) and n), purging the fourth precursor fluid from the third sector of the substrate; and
p) while m), n) and o), flowing the second precursor fluid over the fourth sector of the substrate, wherein a), e), i) and m) are performed sequentially.

14. The method of claim 13 wherein the first precursor fluid is chemically identical to at least one of the second precursor fluid, the third precursor fluid and the fourth precursor fluid.

15. The method of claim 14 wherein the first reagent fluid is chemically identical to at least on of the second reagent fluid, the third reagent fluid and the fourth reagent fluid.

16. A method of processing a substrate, comprising:
a) flowing a first reagent fluid over a first sector of a substrate;
b) while a), purging a second reagent fluid from a second sector of the substrate; and
c) purging the first reagent fluid from the first sector of the substrate, wherein a) and c) are performed sequentially.

17. The method of claim 16 wherein the first reagent fluid is chemically identical to the second reagent fluid.

18. The method of claim 16 further comprising purging a third sector of the substrate.

19. The method of claim 16 further comprising:
d) purging a first precursor fluid from the first sector of the substrate;
e) while d), flowing the second reagent fluid over the second sector of the substrate; and
f) while d) and e), purging a third reagent fluid from a third sector of the substrate, wherein d) is performed prior to steps a) and c).

20. The method of claim 19 wherein the third reagent fluid is chemically identical to at least one of the first reagent fluid and the second reagent fluid.
